(19) United States
(12) Patent Application Publication
(10) Pub. No.: US 2009/0218579 A1
(43) Pub. Date: Sep. 3, 2009

(54) SUBSTRATE HEATING APPARATUS, SEMICONDUCTOR DEVICE MANUFACTURING METHOD, AND SEMICONDUCTOR DEVICE

(75) Inventor: Masami Shibagaki, Fuchu-shi (JP)

Correspondence Address: FITZPATRICK CELLA HARPER & SCINTO, 30 ROCKEFELLER PLAZA, NEW YORK, NY, 10112, US

(73) Assignee: CANON ANELVA ENGINEERING CORPORATION, Kawasaki-shi (JP)

(21) Appl. No.: 12/391,345

(22) Filed: Feb. 24, 2009

(30) Foreign Application Priority Data
Feb. 29, 2008 (JP) 2008-049914

(51) Int. Cl. H01L 29/24; H01L 21/67; H01L 21/04

(52) U.S. Cl. 257/77; 219/444.1; 438/476; 257/E21.054; 257/E29.104

(57) ABSTRACT

In a substrate heating apparatus, thermoelectrons generated by a filament (132) in a vacuum heating vessel (103) are accelerated to collide against a conductive heater (131) which forms one surface of the vacuum heating vessel (103), thus generating heat. The conductive heater (131) is made of carbon. At least one of the inner and outer surfaces of the conductive heater (131) is coated with tantalum carbide (TaC).

### BACKGROUND OF THE INVENTION

1. Field of the Invention

The present invention relates to a substrate heating apparatus, semiconductor device manufacturing method, and semiconductor device.

2. Description of the Related Art

In general, a semiconductor device manufacturing technique frequently requires a process for heating a semiconductor substrate quickly.

In particular, activation annealing of a wide bandgap semiconductor represented by silicon carbide (SiC) as disclosed in non-patent reference 1 (T. Kimoto, N. Inoue and H. Matsunami: Phys. Stat. Sol. (a) Vol. 162 (1997), p. 263) generally requires a high temperature of 1,600° C. or more.

In such annealing, when forming an aluminum-implanted p-well, it is very important in terms of the reliability of a semiconductor device to electrically activate the implanted impurity by 100%, thus restoring complete crystals.

To raise such an activation annealing process to the industrial level, it is necessary to complete the heating process quickly and improve the processing capability of a substrate heating apparatus.

Namely, a process at an ultra-high temperature (2,000° C. or more) which is equal to or higher than the conventionally feasible temperature is necessary.

The conventional substrate heating apparatus described above employs, as a carbon conductive heater which is heated upon collision of accelerated electrons, one in which carbon undergoes a pyrolytic carbon coating process. This conductive heater utilizes the generally known gas impermeability and the properties that coated pyrolytic carbon does not separate easily.

In general, however, the temperature to perform a coating process using pyrolytic carbon which is available stably is approximately 1,800° C., as disclosed in Japanese Patent Laid-Open No. 10-45474. After the coating process, the conductive heater is heated at 2,000° C. for 3 hr in a halogen gas atmosphere, thus densifying the carbon coating film.

When the conductive heater fabricated in the above manufacturing method is used under heating at approximately 2,000° C., pyrolytic carbon sublimates from the pyrolytic carbon coating film actively. This may sharply, undesirably increase the internal pressure of the conductive heater.

This sharp temperature increase causes abnormal electric discharge in the conductive heater, thus damaging the filament. The carbon conductive heater coated with pyrolytic carbon may not be used stably and industrially at a high temperature of 2,000° C. or more.

### SUMMARY OF THE INVENTION

It is an object of the present invention to provide a substrate heating apparatus in which the internal pressure of a conductive heater can be maintained at the regulated value of 1.0×10⁻² Pa or less over a long period of time even in a high-temperature process exceeding 2,000° C., a semiconductor device manufacturing method, and a semiconductor device.

It is accordingly another object of the present invention to provide a substrate heating apparatus that can electrically activate, by 100%, an impurity implanted in silicon carbide (SiC), thus eliminating crystal defects within a practical period of time, a semiconductor device manufacturing method, and a semiconductor device.

According to one aspect of the present invention, there is provided a substrate heating apparatus including a filament arranged in a vacuum heating vessel and connected to a filament power supply to generate thermoelectrons, and an acceleration power supply for accelerating the thermoelectrons between the filament and a conductive heater formed of one surface of the vacuum heating vessel, so that the thermoelectrons generated by the filament are caused to collide against the conductive heater and heat the conductive heater, the apparatus comprising

a coating portion which covers at least one of an inner surface and outer surface of the conductive heater,

wherein the coating portion is coated with tantalum carbide (TaC).

According to another aspect of the present invention, there is provided a semiconductor device manufacturing method comprising a step of heating in a vacuum an ion-implanted silicon carbide (SiC) substrate using a substrate heating apparatus according to one aspect of the present invention.

According to still another aspect of the present invention, there is provided a semiconductor device manufactured by a manufacturing method according to another aspect of the present invention.

According to the present invention, abnormal electric discharge is eliminated by suppressing gas emission from the carbon heater even at an ultra-high temperature of 2,000° C. or more, thus achieving long-term stability of the filament.

Furthermore, in activation annealing of the ion-implanted silicon carbide (SiC), an ultra-high temperature, quick process can be stably performed over a long period of time.

Thus, in the manufacture of a silicon carbide (SiC) semiconductor device, electrical activation of the ion-implanted impurity by 100% and elimination of crystal defects can be realized at the industrial level. As a result, a highly reliable semiconductor device can be manufactured at high productivity.

Further features of the present invention will become apparent from the following description of an exemplary embodiment with reference to the attached drawings.

### BRIEF DESCRIPTION OF THE DRAWINGS

FIG. 1 is a sectional view showing a substrate heating apparatus according to an embodiment of the present invention;

FIG. 2 is an enlarged sectional view showing a conductive heater 131 in the substrate heating apparatus according to the embodiment of the present invention;

FIG. 3 is a perspective view showing an example of a filament employed in the embodiment of the present invention;

FIG. 4 is a perspective view showing carbon conductive heaters each employed in the substrate heating apparatus according to the embodiment of the present invention; and

FIG. 5 is a graph showing the relationship between an activation ratio in a sample employed in the embodiment of the present invention and a process temperature.

### DESCRIPTION OF THE EMBODIMENT

The best embodiment to practice the present invention will be described hereinafter with reference to the accompanying drawings.

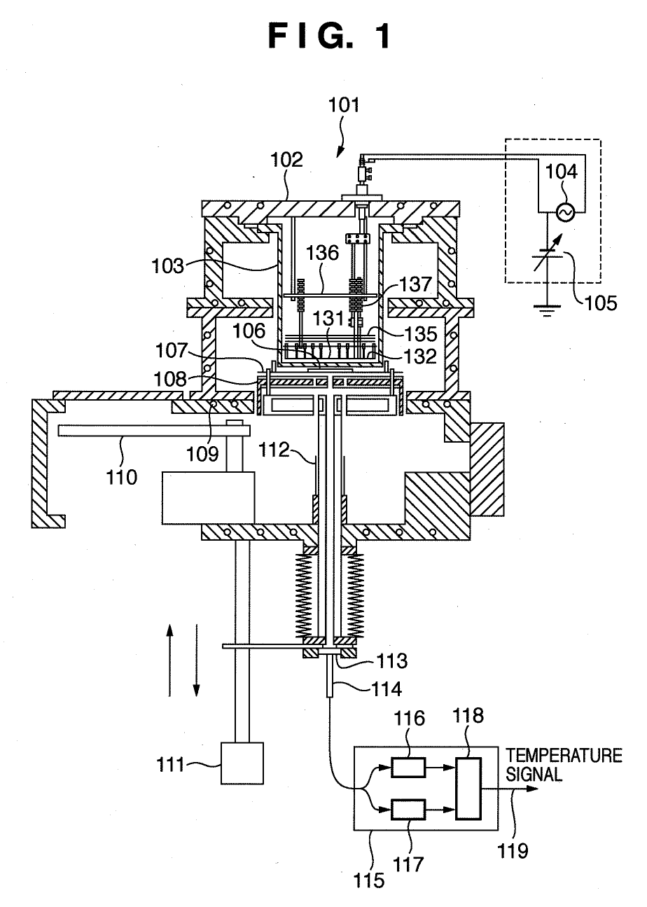

FIG. 1 is a sectional view showing a substrate heating apparatus according to an embodiment of the present invention.

As shown in FIG. 1, a substrate heating apparatus 101 of this embodiment includes a vacuum chamber 102, vacuum heating vessel 103, filament power supply 104, high-voltage power supply 105, substrate 106, substrate stage 107, and substrate holding table 108. The substrate heating apparatus 101 also includes a carbon conductive heater 131, water-cooling channel 109, water-cooled shutter 110, moving mechanism 111, and lift pins 112. The substrate heating apparatus 101 further includes a two-wavelength-type radiation thermometer 115, wavelength detection element a 116, wavelength detection element b 117, arithmetic circuit 118, temperature signal 119, condensing portion 114, and transmission window 113. The substrate heating apparatus 101 also includes a filament 132, heat reflecting plates 135, insulating glass members 137, and intermediate base plate 136.

In the vacuum chamber 102 (vacuum vessel), the conductive heater 131 is stationarily arranged at the lower portion of the vacuum heating vessel 103.

Thermoelectrons generated by the filament 132 are accelerated to collide against the conductive heater 131 constituting one surface of the vacuum heating vessel 103, thus generating heat.

The substrate holding table 108 is arranged, together with the moving mechanism 111, at a position opposing the conductive heater 131 to be vertically movable.

A turbo molecular pump (not shown) (with a stroke volume of 450 L/sec) can evacuate the vacuum chamber 102 on the order of 10⁻⁵ Pa.

The conductive heater 131 incorporates the filament 132 made of tungsten, tungsten-rhenium, or a refractory metal. The filament 132 is coated with pyrolytic carbon.

The filament 132 in the vacuum heating vessel 103 is connected to the filament power supply 104 for heating the filament 132 and the high-voltage power supply 105 through a current lead-in terminal (not shown). The high-voltage power supply 105 forms a potential difference between the filament 132 and conductive heater 131 to accelerate thermoelectrons. The current input terminal can also isolate the vacuum from the atmosphere.

For example, the two-wavelength-type radiation thermometer 115 serving as a temperature measurement means is built under the substrate holding table 108. As the temperature measurement means, other than the radiation thermometer 115, two-wavelength-type thermography can be used. Upon measurement of the temperature of the lower surface of the substrate stage 107 supported by the substrate holding table 108, the current value to be supplied by the filament 132 is controlled through the arithmetic circuit 118 so that the substrate stage 107 reaches a desired temperature.

When transporting a substrate 106 to be processed to the substrate stage 107, the substrate holding table 108 moves downward, and the water-cooled shutter 110 as a heat insulation plate is inserted between the conductive heater 131 and substrate holding table 108. As a result, the conductive heater 131 and substrate holding table 108 are thermally disconnected from each other.

An arm (not shown) extends from a transport chamber (not shown) which is separated from the vacuum chamber 102 by a slit valve and evacuated to a vacuum. The substrate 106 is placed on the arm. The arm then contracts, and the slit valve is closed.

After that, the substrate holding table 108 moves upward and catches the substrate 106 from the lift pins 112. The substrate 106 is transferred to the substrate stage 107. The substrate holding table 108 further moves upward until the distance between the substrate 106 and conductive heater 131 is, e.g., 5 mm, and stops.

After that, the AC current to the filament 132 in the vacuum heating vessel 103 is increased from 0 A to a desired value by several A/sec, and held at a desired value for a desired period of time, thus preheating the filament 132.

After that, the high-voltage power supply 105 increases the voltage applied between the filament 132 and conductive heater 131 from 0 V to a desired value by a desired V/sec, so that the filament 132 emits thermoelectrons.

Then, the emission current is gradually emitted. After the voltage is increased to a desired value, the AC current value is increased to a desired value, and simultaneously the voltage of the high-voltage power supply 105 is further increased to a desired value.

While monitoring the temperature of the substrate stage 107 by the two-wavelength-type radiation thermometer 115, the arithmetic circuit 118 controls the AC current value of the filament power supply 104 to increase it to a desired value in several min. This heating is kept for a desired period of time. Then, the filament power supply 104 and the high-voltage power supply 105 are turned off.

The temperature of the conductive heater 131 decreases quickly by radiation. When the temperature of the substrate stage 107 decreases to a predetermined value in about 1 min, the substrate stage 107 moves downward. Away from conductive heater 131 by 50 mm, the water-cooled shutter 110 serving as the heat insulation plate is inserted between the conductive heater 131 and substrate stage 107, to cool the substrate quickly.

Several min later, when the temperature of the substrate stage 107 drops to a desired value or less, the substrate holding table 108 further moves downward. The substrate 106 is placed on the lift pins 112, and the slit valve is opened.

The arm (not shown) extends from the transport chamber (not shown) which is separated from the vacuum chamber 102 by the slit valve and evacuated to a vacuum. The arm recovers the processed substrate 106 from the lift pins 112 and transports it to a load-lock chamber (not shown).

When the temperature of the substrate 106 drops to a desired temperature or less, the load-lock chamber (not shown) is open to the atmosphere, and the substrate 106 is taken out from it.

At this time, usually, the conductive heater 131 is evacuated by another TMP (Turbo Molecular Pump) independent of the turbo molecular pump (not shown) that evacuates the vacuum chamber 102 where the substrate 106 is placed. Alternatively, the conductive heater 131 can be evacuated simultaneously by the TMP that evacuates the vacuum chamber 102.

In general, silicon carbide (SiC) to form a substrate is available in a plurality of crystal types, e.g., 3C, 4H, and 6H. To allow homoepitaxial growth with uniform crystallinity, a silicon carbide (SiC) substrate in which crystals are inclined by 4° or 8° with respect to the C-axis plane is used.

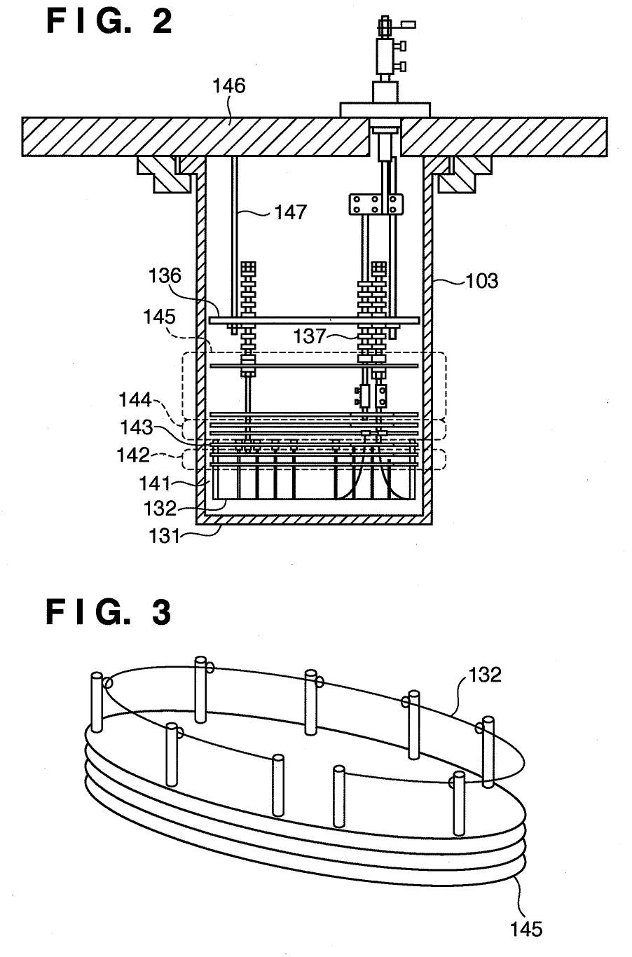

FIG. 2 is an enlarged sectional view showing the conductive heater 131 in the substrate heating apparatus 101 according to the embodiment of the present invention.

As shown in FIG. 2, the conductive heater 131 includes the filament 132, intermediate base plate 136, and insulating glass members 137. The conductive heater 131 also includes filament support columns 141, heat receiving plates 142, base plate 143, heat receiving plates 144, reflecting plates 145, water-cooled flange 146, and support columns 147.

According to this embodiment, the filament support columns 141 are made of tantalum. The heat receiving plates 142, base plate 143, and heat receiving plates 144 are made of carbon. The reflecting plates 145, intermediate base plate 136, and support columns 147 are made of molybdenum.

The conductive heater 131 is fabricated with a diameter of approximately 200 mm.

The filament support columns 141 stand on the base plate 143 and fix the filament 132.

The heat receiving plates 142 and 144 sandwich the base plate 143. The heat receiving plates 142 and 144 suppress a temperature difference between the upper and lower surfaces of the base plate 143.

Furthermore, the plurality of reflecting plates 145 with surfaces that are processed to decrease the emissivity are arranged between the heat receiving plates 144 and the intermediate base plate 136 which supports supporting member including the filament 132. This arrangement increases the heating efficiency.

The base plate 143 is stationarily fixed to the intermediate base plate 136 through molybdenum support columns.

The filament 132 is provided with the filament power supply for heating the filament and the high-voltage power supply which forms a potential difference between the filament 132 and the conductive heater 131.

The base plate 143, heat receiving plates 142 and 144, and reflecting plates 145 are set to have the same potential as that of the filament 132. This is aimed at allowing efficient reflection of the thermoelectrons, so that the thermoelectrons collide against the conductive heater 131 efficiently.

FIG. 3 is a perspective view showing an example of a filament employed in the embodiment of the present invention.

In this embodiment, a single-loop filament as shown in FIG. 3 is employed. Other than this, a multi-coil filament can also be employed.

The filament 132 is connected parallel with the AC filament power supply and DC high-voltage power supply through the current input terminal insulated from the vacuum. Thus, the thermoelectrons are generated and accelerated.

The conductive heater coated with pyrolytic carbon is placed outside the filament 132, so that the thermoelectrons generated by the filament 132 and accelerated collide against the conductive heater 131 and heat it.

A silicon carbide (SiC) substrate to be heated is placed on the substrate holder to oppose the conductive heater. The substrate holder moves the silicon carbide substrate to a position close to but noncontact with the conductive heater. The silicon carbide substrate is heated in the vacuum atmosphere.

At this time, usually, the conductive heater is evacuated by another TMP independent of the turbo molecular pump (TMP) that evacuates the vacuum chamber where the substrate is placed. Alternatively, the conductive heater can be evacuated simultaneously by the TMP that evacuates the vacuum chamber.

In the substrate heating apparatus, an ion gauge monitors the internal pressure of the heater so that abnormal electric discharge caused by the internal pressure of the conductive heater is prevented. When the internal pressure of the heater becomes 1.0×10⁻² Pa or more, power from the high-voltage power supply is interrupted automatically, thus protecting the apparatus.

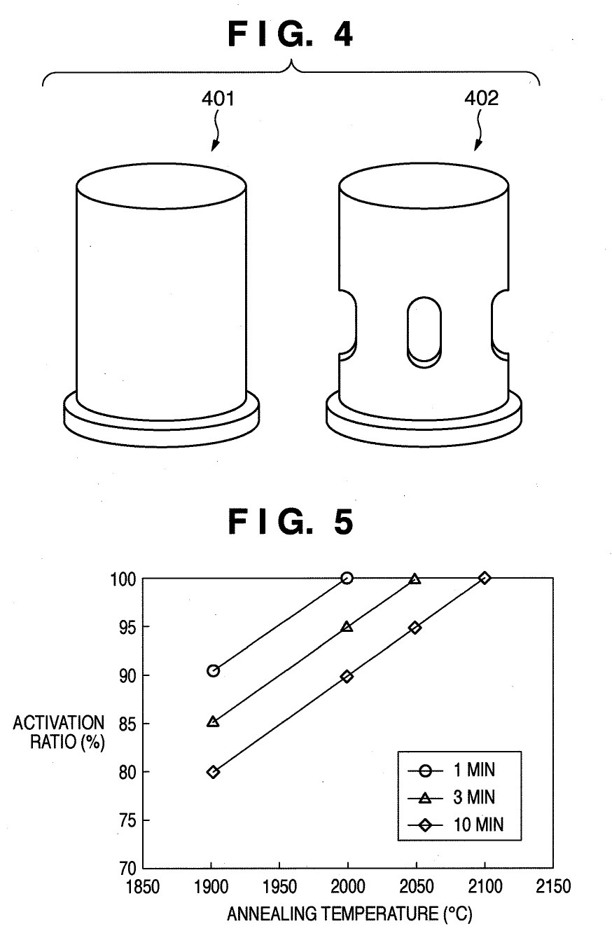

FIG. 4 is a perspective view showing carbon conductive heaters (401, 402) each employed in the substrate heating apparatus according to the embodiment of the present invention.

As the base material of the conductive heaters (401, 402), isotropic graphite is employed, so that the coefficient of linear thermal expansion of the heater becomes almost equal to that (7.1×10⁻⁶/K) of tantalum carbide (TaC).

The carbon conductive heaters (401, 402) were fabricated in the following manner.

First, the base material was machined by a lathe into a cylinder. The cylinder underwent a high purification process employing a high-temperature process in a halogen gas atmosphere.

After that, using a tantalum organic source, the cylinder was coated with tantalum carbide (TaC) by a thermal vapor reaction (thermal CVD) at a high temperature of 2,100° C. or more, so that the content ratio of tantalum to carbide became almost 1:1.

This coating was performed to coat at least one of the inner and outer surfaces of the conductive heaters (401, 402) with tantalum carbide.

Reference numeral 401 in FIG. 4 denotes a cylindrical vacuum vessel structure having a seal surface on a side opposite to a heating portion so that the interior of the conductive heater can be evacuated by an independent evacuation system. Reference numeral 402 in FIG. 4 denotes a structure provided with an evacuation window so that a process chamber pump can evacuate the interior of the conductive heater simultaneously.

Table 1 shows measurement results of pressures in the conductive heater of this embodiment and a conventional conductive heater obtained before the heaters are not in use (when they are band-new) and after they are heated for a heating time of 50 hr and held to stand still for 10 min.

(1) Brand-New Conducive Heater

| | 1,900° C. | 2,000° C. | 2,050° C. | 2,100° C. |
|---|---|---|---|---|
| Prior Art | 7.0 × 10⁻⁴ | 3.2 × 10⁻³ | 9.8 × 10⁻³ | Cannot be |
| (Pa) | | | | Heated |
| Embodiment | 3.1 × 10⁻⁴ | 3.9 × 10⁻⁴ | 4.2 × 10⁻⁴ | 4.3 × 10⁻⁴ |
| (Pa) | | | | |

(2) Conductive Heater after Heating for 50 hr

| | 1,900° C. | 2,000° C. | 2,050° C. | 2,100° C. |
|---|---|---|---|---|
| Prior Art | 4.5 × 10⁻³ | 9.5 × 10⁻³ | Cannot be | Cannot be |
| (Pa) | | | Heated | Heated |
| Embodiment | 3.1 × 10⁻⁴ | 3.9 × 10⁻⁴ | 4.3 × 10⁻⁴ | 4.5 × 10⁻⁴ |
| (Pa) | | | | |

The conductive heater according to this embodiment is obtained by coating the conventional conductive heater with tantalum carbide (TaC), and the conventional conductive heater is obtained using a base material coated with pyrolytic carbon.

As shown in Table 1, the internal pressure of the conductive heater coated with tantalum carbide (TaC) is on the order of 10⁻⁴ Pa both before and after it is held heated at 2,100° C. for 50 hr. This value is much smaller than the interlock pressure of 1.0×10⁻² Pa at which the power is interrupted to prevent abnormal electric discharge. Hence, high-temperature heating can be realized stably.

A semiconductor device manufacturing method by means of annealing, using the conductive heater according to this embodiment, to activate a semiconductor substrate obtained by implanting ions into a silicon carbide (SiC) substrate will be described hereinafter.

The substrate having an n⁺-type silicon carbide (SiC) epitaxial layer of a thickness of 10 μm grown by chemical vapor deposition (CVD method) on an n-type 4H—SiC(0001) substrate with an off angle of 4° was employed. Nitrogen was implanted as a dopant in an n⁺-type silicon carbide (SiC) epitaxial layer.

First, RCA cleaning, sacrificial oxidation, and a hydrofluoric acid process were performed.

After that, a sample on which a protective oxide film for ion implantation was deposited to a thickness of 10 nm was heated to 500° C. by an ion implantation machine that can raise the substrate temperature.

Aluminum was implanted into the sample at an energy of 40 keV to 700 keV and an implantation concentration of 2.0×10¹⁸/cm³ to a depth of 0.8 μm in a multiple stage manner to form a box profile.

Subsequently, the protective oxidation film was removed by a hydrofluoric acid process. This sample was then activated by the heating apparatus according to this embodiment. The temperature/time dependency of the activation ratio obtained by dividing the carrier concentration measured by CV measurement by the implantation amount was evaluated.

Simultaneously, the surface flatness within the range of 4 μm×4 μm after the activation process was measured by atomic force microscopy (AFM) in the tapping mode.

FIG. 5 is a graph showing the relationship between the activation ratio in the sample employed in this embodiment and the process temperature.

As shown in FIG. 5, with the substrate heating apparatus employing the conventional conductive heater, when the activation annealing temperature was 2,000° C., it took 10 min for the activation ratio to reach 100%.

A processing method with the substrate heating apparatus employing the conductive heater according to this embodiment was performed. When the activation annealing temperature was 2,050° C., the activation ratio reached 100% in 3 min; when 2,100° C., in 1 min.

At this time, the RMS value (Root-Mean-Square Value) representing the surface flatness was 1.0 nm or less for the activation annealing temperature of both 2,050° C. and 2,100° C., thus indicating a very high flatness.

When 0.1 sccm of silane (SiH₄) gas was added during activation annealing, the RMS value exhibited 0.89 nm even when the process temperature was 2,100° C. The surface flatness was ensured more easily.

In the conventional conductive heater, the silane gas corroded the heater surface. In the conductive heater of this embodiment, no surface corrosion was observed. Thus, the conductive heater of this embodiment was able to be used stably.

According to the semiconductor device manufacturing method by means of annealing using the substrate heating apparatus of this embodiment, the process at an ultra-high temperature exceeding 2,000° C. was completed quickly. Also, the impurity implanted in the silicon carbide (SiC) substrate was electrically activated by 100%, thus eliminating residual crystal defects.

As a result, fabrication of a highly reliable semiconductor device using silicon carbide (SiC) was enabled.

The present invention can be utilized by a substrate heating apparatus used for annealing for the purpose of, e.g., activation of elements formed on a substrate such as a silicon carbide substrate.

While the present invention has been described with reference to an exemplary embodiment, it is to be understood that the invention is not limited to the disclosed exemplary embodiment. The scope of the following claims is to be accorded the broadest interpretation so as to encompass all such modifications and equivalent structures and functions.

This application claims the benefit of Japanese Patent Application No. 2008-049914, filed Feb. 29, 2008, which is hereby incorporated by reference herein in its entirety.

What is claimed is:

1. A substrate heating apparatus including a filament arranged in a vacuum heating vessel and connected to a filament power supply to generate thermoelectrons, and an acceleration power supply for accelerating the thermoelectrons between said filament and a conductive heater formed of one surface of the vacuum heating vessel, so that the thermoelectrons generated by said filament are caused to collide against the conductive heater and heat the conductive heater, the apparatus comprising
a coating portion which covers at least one of an inner surface and outer surface of the conductive heater,
wherein said coating portion is coated with tantalum carbide (TaC).

2. A semiconductor device manufacturing method comprising a step of heating in a vacuum an ion-implanted silicon carbide (SiC) substrate using a substrate heating apparatus according to claim 1.

3. The method according to claim 2, further comprising a step of adding a gas containing at least one of silicon (Si) and hydrogen (H) during heating in the vacuum.

4. A semiconductor device manufactured by a manufacturing method according to claim 2.
